(19) United States
(12) Patent Application Publication
(10) Pub. No.: US 2014/0086523 A1
(43) Pub. Date: Mar. 27, 2014

(54) POLING STRUCTURES AND METHODS FOR PHOTONIC DEVICES EMPLOYING ELECTRO-OPTICAL POLYMERS

(71) Applicants: Bruce A. BLOCK, Portland, OR (US); Mauro J. KOBRINSKY, Portland, OR (US); Miriam R. RESHOTKO, Portland, OR (US); Shawna M. Liff, Gilbert, AZ (US)

(72) Inventors: Bruce A. BLOCK, Portland, OR (US); Mauro J. KOBRINSKY, Portland, OR (US); Miriam R. RESHOTKO, Portland, OR (US); Shawna M. Liff, Gilbert, AZ (US)

(21) Appl. No.: 13/629,396

(22) Filed: Sep. 27, 2012

(51) Int. Cl. G02B 6/26; H05K 13/00; G02F 1/035

(52) U.S. Cl. 385/3; 385/50; 385/2; 29/592.1

(57) ABSTRACT

EOP-based photonic devices employing coplanar electrodes and in-plane poled chromophores and methods of their manufacture. In an individual EOP-based photonic device, enhanced performance is achieved through in-plane poled chromophores having opposing polarities, enabling, for example, a push-pull optical modulator with reduced operational voltage and switching power relative to a conventional MZ modulator. For a plurality of EOP-based photonic devices, enhanced manufacturability is achieved through a sacrificial interconnect enabling concurrent in-plane poling of many EOP regions disposed on a substrate.

### TECHNICAL FIELD

Embodiments of the invention are generally related to semiconductor devices, and more particularly to photonic integrated circuits (PICs) employing Electro-Optical Polymers (EOP) and their fabrication.

### BACKGROUND

Monolithically integrated photonic circuits are useful as optical data links in applications such as, but not limited to, high performance computing (HPC), optical memory extension (OME), and inter-device interconnects. For mobile computing platforms too, a PIC is a useful means of I/O to rapidly update or sync a mobile device with a host device and/or cloud service where a wireless or electrical link has insufficient bandwidth. Such optical links utilize an optical I/O interface in that includes an optical transmitter and an optical receiver.

Certain PICs may include one or more photonic devices that include an Electro-Optical Polymer (EOP). EOPs are active materials which have an optical index than can be varied through application of an electric field, and are compatible with conventional microelectronic fabrication processes (e.g., silicon-based PIC processes). A planar lightwave circuit (PLC) is one application where an optical modulator including an EOP may be advantageous. To enhance their optical properties, EOP regions of a PLC are poled. Poling is the process by which chromophores (electro-optically active molecules) in the EOP are aligned in an electric field.

Currently, most EOP-based photonic devices are fabricated with a vertical electrode configuration where either a blanket deposited metal layer and a contact charging technique, or a corona discharge technique is employed to pole the EOP regions with an electric field that is oriented out-of-plane (i.e., normal to surface of a substrate). Such methods however are not applicable for devices with coplanar electrodes (e.g., electrode formed in a single metal layer).

While EOP-based photonic devices with coplanar electrodes would be advantageous, in-plane poling of a great many of such devices (e.g., wafer-level) is not possible with existing methods and device architectures.

### BRIEF DESCRIPTION OF THE DRAWINGS

Embodiments of the present invention are illustrated by way of example, and not by way of limitation, and can be more fully understood with reference to the following detailed description when considered in connection with the figures in which:

FIG. 1A is a flow diagram illustrating a method of fabricating a photonic device, in accordance with an embodiment;

FIG. 1B is a flow diagram illustrating a method of fabricating a plurality of photonic devices, in accordance with an embodiment;

FIG. 2A is a plan view of a push-pull optical modulator during poling, in accordance with an embodiment;

FIG. 2B is a plan view of a push-pull optical modulator in an operative state, in accordance with an embodiment;

FIG. 2C is a plan view of a push-pull optical modulator, in accordance with an embodiment;

FIG. 3A is a plan view of a plurality of MZ modulators during poling, in accordance with an embodiment;

FIG. 3B is a plan view of a plurality of MZ modulators in operative states, in accordance with an embodiment;

FIG. 3C is a plan view of a plurality of RO modulators during poling, in accordance with an embodiment;

FIG. 3D is a plan view of a plurality of RO modulators in operative states, in accordance with an embodiment;

FIG. 4A is cross-sectional view of a plurality of photonic devices during poling, in accordance with an embodiment;

FIG. 4B is cross-sectional view of a plurality of photonic devices in operative states, in accordance with an embodiment;

FIG. 5 is a schematic diagram of a mobile device including an optical transmitter, in accordance with embodiments of the present invention; and

FIG. 6, is a function block diagram of the mobile device illustrated in FIG. 10, in accordance with an embodiment of the present invention.

### DETAILED DESCRIPTION

In the following description, numerous details are set forth, however, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “in one embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not specified to be mutually exclusive.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” my be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

Described herein are EOP-based photonic devices employing coplanar electrodes and in-plane poled chromophores and exemplary methods of their manufacture. In the context of an individual EOP-based photonic device, enhanced performance is achieved through in-plane poled chromophores having opposing polarities, enabling, for example, a push-pull optical modulator with reduced operational voltage and switching power relative to a conventional Mach-Zehnder (MZ) modulator. In the context of a plurality of EOP-based photonic devices, enhanced manufacturability is achieved through an interconnect that is at least partially sacrificial, enabling concurrent in-plane poling of many EOP regions disposed on a substrate. To emphasize that the features and benefits described in the context of an individual EOP-based photonic device are applicable and combinable with the features and benefits described in the context of the plurality of EOP-based devices, same reference numbers are carried throughout the description for elements of like structure and/or function.

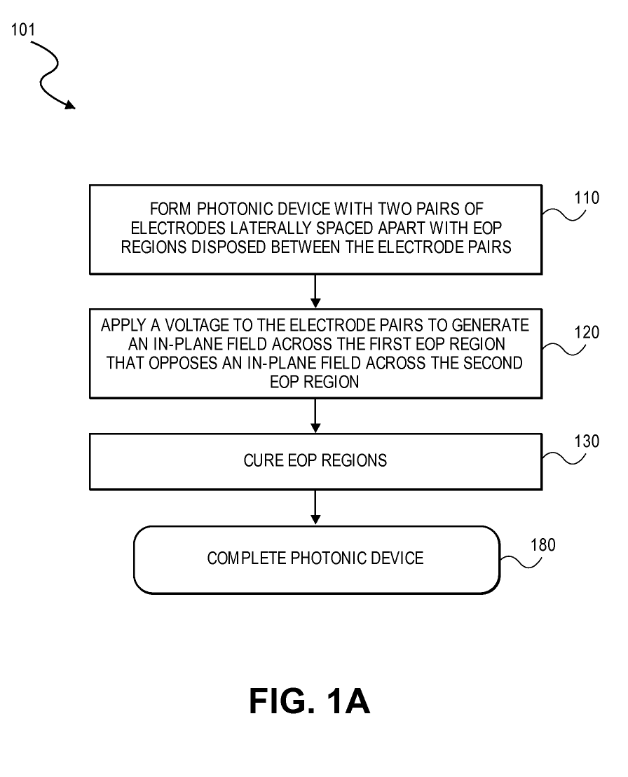

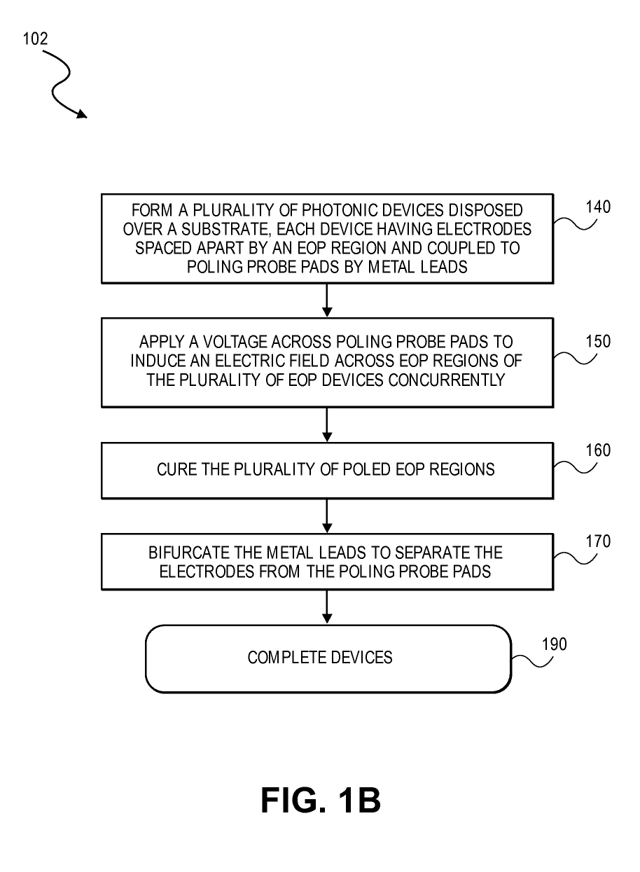

FIG. 1A is a flow diagram illustrating a method 101 of fabricating a photonic device, in accordance with an embodiment. At operation 110 a device is formed with at least two pairs of electrodes laterally spaced apart with an EOP region optically coupled to an optical waveguide disposed between each of the electrode pairs. With the electrodes laterally spaced and in a same plane of a metal level (i.e., “coplanar”), electric fields generated across the EOP material between the electrodes are in the same plane as the underlying substrate (i.e., “in-plane”), rather than “out-of-plane,” or normal to, the substrate plane.

Generally, at operation 110 the optical waveguides may be formed through any conventional processing. A first EOP material may then be deposited over and/or in contact with the first waveguide, and a second EOP material is deposited over and/or in contact with the second waveguide. The EOP materials may be of a same and conventional composition, as embodiments of the present are not limited in this respect. Interlayer dielectric (ILD) may be deposited over the electrodes, vias formed in the ILD, and routing metal then deposited to connect various ones of the electrodes to poling probe pads and/or bond pads.

At operation 120, a voltage is applied across each of the electrode pairs to generate an in-plane field oriented in a first direction across one of the EOP regions and an in-plane field oriented in a second direction, opposite the first, across the other of the EOP regions. In exemplary embodiments, the voltage is applied at operation 120 with an in-line electrical testing apparatus. Any conventional e-tester may be adapted to perform operation 120 by landing on poling probe pads disposed on a substrate, for example with probe tips of a probe card, and applying a voltage across the poling probe pads to generate the in-plane fields while heating the substrate (and EOP). In the presence of the in-plane fields, the EOP regions are heated and cured at operation 130 (i.e., operations 120 and 130 may be performed concurrently). Fabrication of the photonic device is then completed at operation 180. In embodiments, operation 180 entails deposition of a final passivation electrically connecting the pairs of electrodes, for example through bond pad connections, to increase a refractive index of the first EOP region and decrease the refractive index of the second EOP region when a drive signal is applied to the EOP device. Such an operative state is referred to herein as “push-pull” because a signal applied to the EOP device acts upon two EOP regions in a complementary manner, “pushing” on one EOP region and “pulling” on the second EOP region in phase.

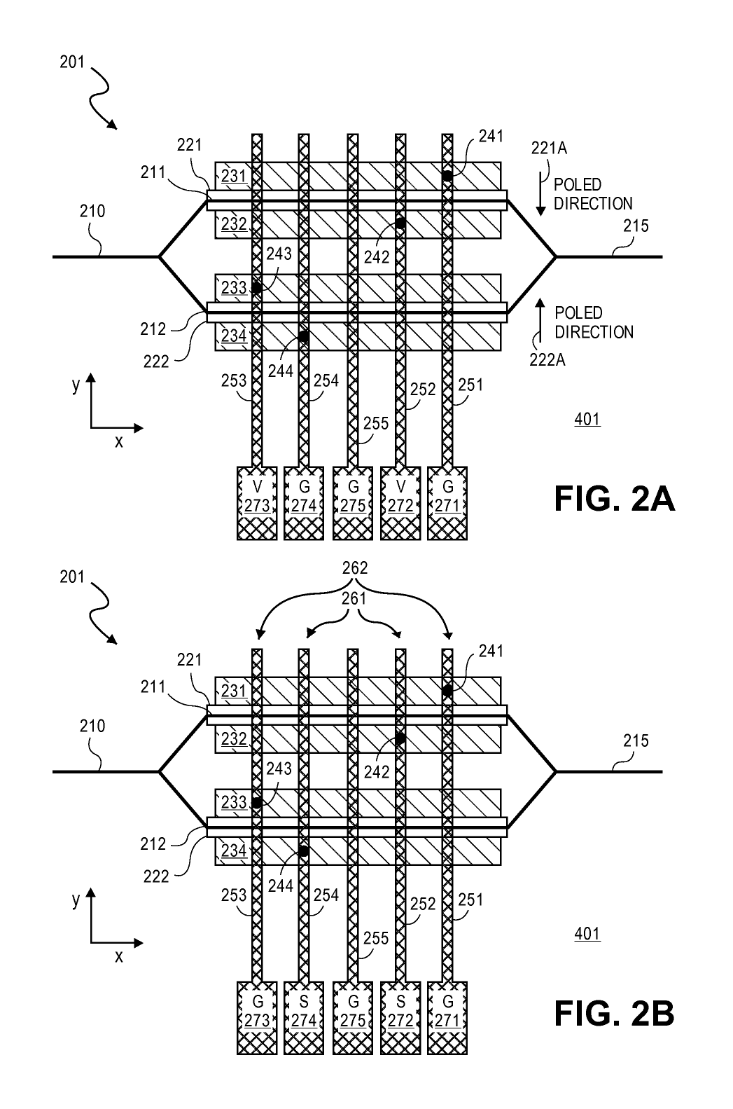

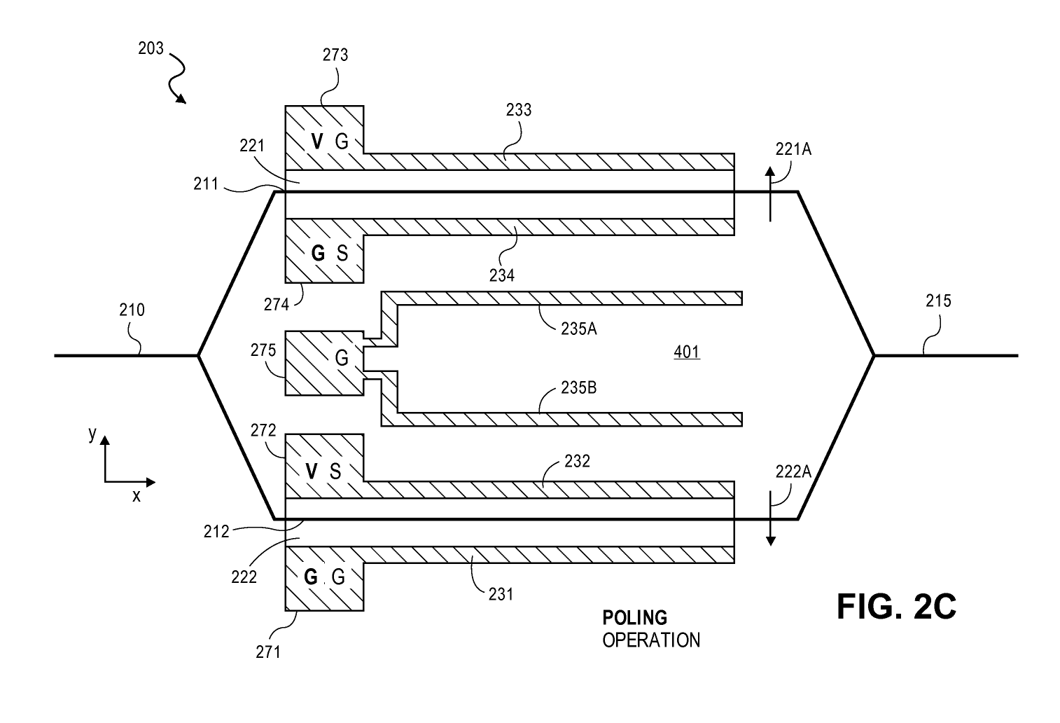

FIG. 2A is a plan view of a coplanar push-pull optical modulator (i.e., a modulator operable in a “push-pull” mode or state) 201 that may be fabricated at operation 110. The modulator 201 is an advancement beyond a basic MZ electro-optical modulator having EOP index modulation along only one arm (and therefore operable only in a push, or pull, mode). As illustrated, the modulator 201 is disposed over a region of a substrate 401. The substrate 401 may be any conventional substrate as embodiments of the present invention are not limited in this respect. Exemplary substrates include, but are not limited to, semiconductor-on-insulator (SOD, III-V semiconductor alloys (e.g., InP, GaAs, etc.), and sapphire. In one particular embodiment, the substrate 401 is a silicon-on-insulator (SOI) substrate.

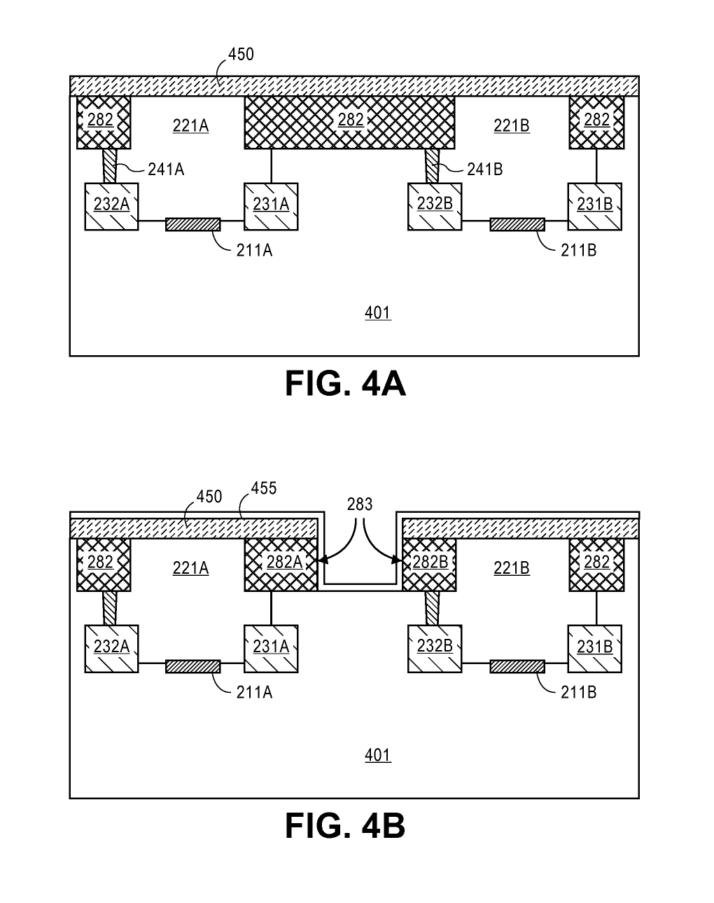

The modulator 201 includes a first optical waveguide 211 and a second optical waveguide 212 with substantially parallel longitudinal lengths extending along the y-dimension and joined at the ends by I/O optical waveguides 210, 215. The optical waveguides 210, 211, 212, and 215 may be of any material known in the art to have suitable properties for mode confinement (e.g., silicon) and have any known morphology (e.g., rib, ridge). Optically coupled to the waveguides 211 and 212 is an EOP 221 and 222, respectively. Disposed a distance apart from sidewalls of the waveguide 211 (e.g., by the EOP 221) is a first pair of coplanar electrodes 231 and 232, while spaced apart from sidewalls of the waveguide 212 (e.g., by EOP 222) is a second pair of coplanar electrodes 233 and 234. In the exemplary embodiment where the EOP 221 is disposed over at least a top of the waveguide 211, the electrodes 231, 232 are spaced apart by the EOP 221, substantially as illustrated in the cross-sectional view provided in FIG. 4A, and as further described elsewhere herein. For such an embodiment, the waveguide 211, electrodes 233, 234, and EOP 221 have a same structural relationship within a second arm of the modulator 201.

The modulator 201 further includes routing metal leads 251, 252, 253, and 254 disposed in a plane other than that of the electrodes (e.g., in a second metal layer above or below that of the electrodes) electrically connecting the four electrodes 231, 232, 233, and 234, through the vias 241, 242, 243, and 244, to poling probe pads 271, 272, 273, and 274, respectively. As illustrated, the routing metal extends across the one or more of the electrodes 231-234, and more particularly, extends substantially orthogonal to the electrodes 231-234 with each one of the metal leads 251-254 coupled to an individual one of the first poling probe pads.

As further illustrated in FIG. 2A, during the poling state, the poling probe pad 272 is biased with a (DC) voltage level V relative to a reference voltage level G (e.g., ground) at the poling probe pad 271. With the coplanar electrodes 231, 232 so biased, an in-plane field orients chromophores the EOP 221 in a first pole (direction) 221A. Similarly, the poling probe pad 273 is biased with the voltage level V relative to the reference voltage level G at the poling probe pad 274. With the coplanar electrodes 233, 234 baised in this manner, an in-plane field orients chromophores in the EOP 221 in a second pole (direction) 222A, opposite the first pole direction 221A.

FIG. 2B is a plan view of the push-pull optical modulator 201 in an operative state, after poling, in accordance with an embodiment. In the operative state, with the EOP 221 retaining the poled direction 221A and the EOP 222 retaining the poled direction 221A, the electrodes 231-234 are coupled to a drive signal source (not depicted) in a manner that results in push-pull modulation. More specifically, the electrodes 231-234 are connected to the drive signal source so that the drive signal acts to increase a refractive index of one EOP region (e.g., 221) and decrease the refractive index of the other EOP region (e.g., 222).

In the embodiment illustrated in FIG. 2B, during operation a drive signal S (e.g., a time varying voltage waveform) is applied to first routing metal (e.g., 261) comprising a first pair of metal leads (e.g., 252, 254) coupled to one electrode of each pair (e.g., 232 and 234) while second routing metal (e.g., 262) including the other pair of metal leads (e.g., 251, 253) coupled to the other electrode of each pair (e.g., 231, 233) is held at a reference voltage, G. In this configuration, an electrode at a fixed reference voltage (e.g., a ground plane) is disposed between the pair of driven electrodes. Assuming the polarity of V and S are the same, because the poling voltage V was applied to the electrodes 232 and 233, and the signal S is applied to the electrodes 232, 234, the in-plane electric field generated in the EOP 221 is in the same direction as the poled direction 221A, while the in-plane electric field generated in the EOP 222 is in the opposite direction as the poled direction 222A. A first refractive index modulation of the EOP 221 therefore combines with a second refractive index modulation of the EOP 222, to more efficiently alter the phase of the light passing through the waveguides 211, 212. Relative to a conventional MZ modulator, such in-plane, push-pull modulator operation has been found capable to reducing operating voltage by a factor of two and switching power by a factor of four.

As further illustrated in FIG. 2B, with the routing metal all on a second level of metal, the routing metal is also co-planar such that a transmission line is advantageously provided. Specifically, with the addition of a fixed ground plane provided by the metal lead 255 (coupled to probe pad 275), the routing metal has a ground-signal-ground-signal ground configuration (e.g., coplanar waveguide). Also of note, the probe pads 271-275, although retained in FIG. 2B to best illustrate the differences between poling and operational modes, need not be utilized as a means of coupling the routing metal to the electrodes, and indeed, using techniques described elsewhere herein, may be disconnected from the routing metal altogether (e.g., to reduce parasitic capacitance). In advantageous embodiments, the routing metal (e.g., 261) may further be connected to bond pad (not depicted) that couples in the drive signal S during operation. Such a bond pad, being of a pristine surface, may serve as a better land for a solder ball, or the like, than would the poling probe pads, which are typically larger (e.g., >50 μm on a side) and would have probe marks (i.e., physical damage) after the poling (e.g., operation 120 in FIG. 1A).

In alternative embodiments, an in-plane push-pull modulator is implemented in a single metal level. FIG. 2C is a plan view of a push-pull optical modulator 203, in accordance with an exemplary single metal level embodiment. As illustrated, the poling pads 271, 272, 273 and 274 further serve portions of the electrodes 231, 232, 233, 234, respectively. As further illustrated, during poling (e.g., operation 120 in FIG. 1A), the voltage level V is applied to ones of the poling pads (e.g., 272 and 273) as just as described for the modulator 201 to pole the EOP 221 in the first pole direction 221A, and the EOP 222 in the second pole direction 222A. During operation of the modulator 203, the drive signal S is applied to the electrodes (e.g., through the poling pads 272, 274), for the same in-plane push-pull mode as was described for the modulator 201. A ground plane is further provided by the leads 235A, 235B coupled to the pad 275.

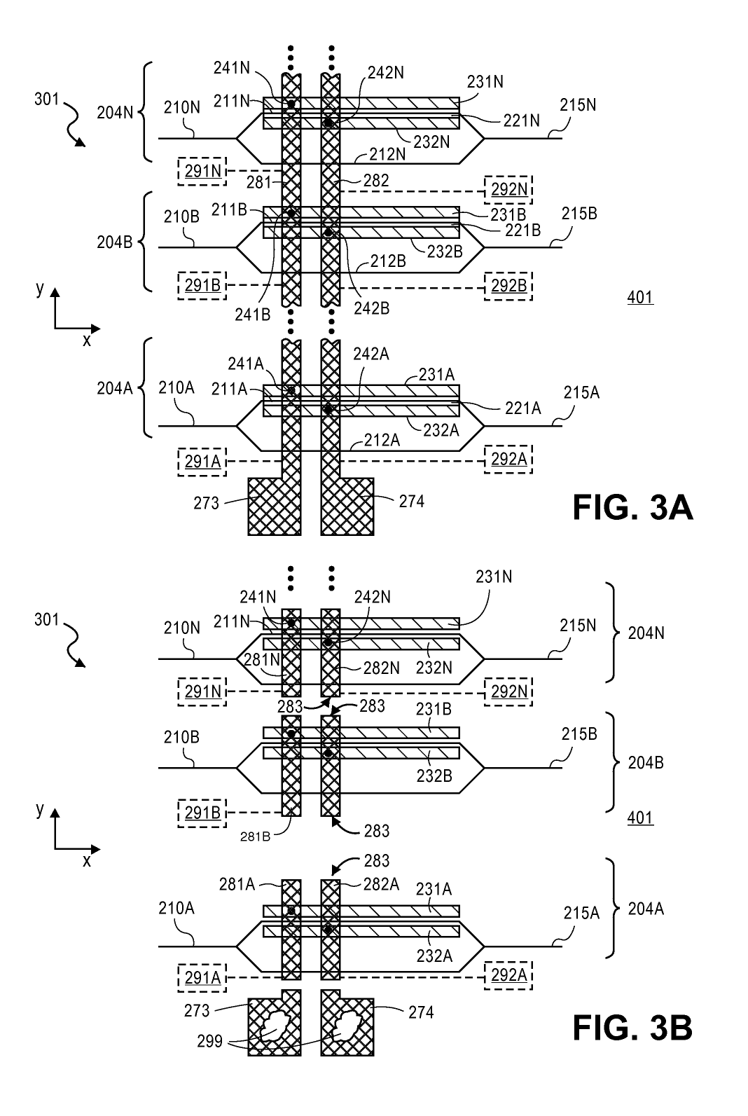

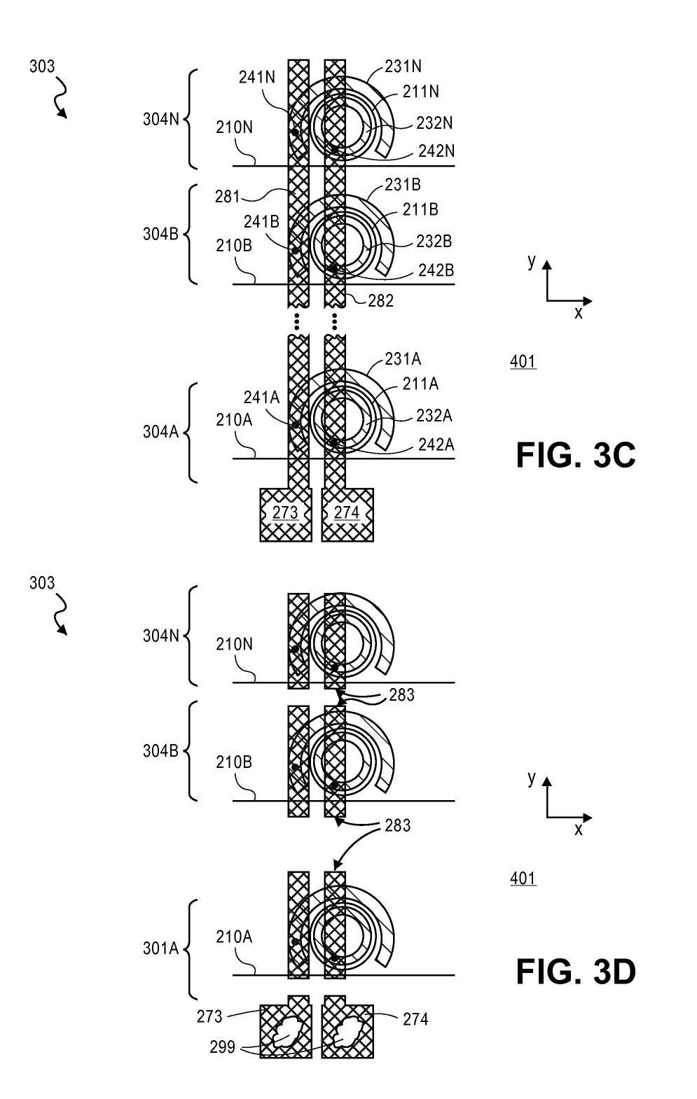

In embodiments, many tens, hundreds, or even thousands of EOP-based photonic devices, such as the modulator 201, are fabricated over a single substrate. In the exemplary embodiments, poling of many devices is performed according to the method 102, illustrated in FIG. 1B. The method 102 is applicable to any photonic device as a technique for poling many such devices concurrently, but is particularly advantageous for those devices utilizing coplanar electrodes. While the method 102 is therefore applicable to the photonic devices previously discussed (e.g., modulator 201), the method 102 is illustrated in the context of a plurality of single arm MZ modulators in FIGS. 3A and 3B for the sake of clarity of description. Double arm push-pull modulator embodiments like those in FIGS. 2A and 2B, can be implemented in the same manner, albeit with twice as many pads and metal leads.

The method 102 begins at operation 140 with formation of a plurality of photonic devices disposed over a substrate. Each photonic device has electrodes spaced apart by an EOP region and electrically coupled to poling probe pads by metal leads. FIG. 3A illustrates a plan view of an exemplary plurality of n MZ optical modulators 301 disposed over the substrate 401. The modulator 204A includes two waveguides 211A and 212A joined at their ends to I/O waveguides 210A, 215A. The waveguide 211A is optically coupled to an EOP region 221A disposed between two coplanar electrodes 231A and 232A. The modulators 204B, and 204N, being for purposes herein identical to the modulator 204A, also include optical waveguides 210B, 210N, 211B, 211N, 212B, 212N, 215B, and 215N, the EOP regions 221B, 221N, as well-as electrodes 231B, 232B and 231N, 232N, respectively.

As further illustrated in FIG. 3A, the electrode pairs from each modulator 204A-204N are electrically coupled to routing metal leads 281 and 282 extending across one or more of the modulators and disposed in a plane other than that of the electrodes (e.g., a second level of metal). In this exemplary embodiment, the routing metal lead 281 is connected to a vias 241A, 241B, 241N that are further connected to electrodes 231A, 231B, and 231N. The metal lead 282 is connected to vias 242A, 242B, 242N that are further connected to electrodes 232A, 232B, and 232N. The routing metal leads 281 and 282 are further connected to poling probe pads 273, 274, respectively. The metal lead 281 therefore shorts together first electrodes from each of the plurality of modulators while the metal lead 282 shorts together second electrodes from each of the plurality of modulators.

Returning to FIG. 1B, at operation 150, poling of a plurality of EOP regions is performed by applying a voltage across two poling pads to concurrently induce an electric field across the EOP regions of all EOP-based optical devices connected to the poling pads. In the exemplary embodiment illustrated in FIG. 3A, two probes are landed on the two poling probe pads 273 and 274 and a poling voltage V applied. With the routing metal leads 281, 282 shorting together respective ones of the electrodes across the plurality of devices, poling of all photonic devices proceeds in parallel. Curing at operation 160 (FIG. 1B) may therefore also occur across the entire substrate, for example while the poling fields in the plane of the substrate are generated.

At operation 170, the routing metal leads coupling the plurality of photonic device electrodes are bifurcated to electrically isolate, or separate, the electrodes from the poling probe pads. Electrically isolating the poling probe pads may be advantageous as the large-sized probe pads incur parasitic capacitance and may also be physically damaged by probe marks 299 (FIG. 3B). In embodiments, each bifurcated routing metal lead includes at least one metal lead segment that is electrically isolated from the poling probe pads and is also electrically connected by a via to one of the electrodes. In embodiments, bifurcating a metal lead entails etching and/or polishing through portions of a metal lead extending between adjacent photonic devices. As such, while the routing metal leads may be considered at least partially sacrificial, some portions, or segments, of the routing metal may be permanently retained and visible in an operational device (i.e. non-sacrificial).

In certain embodiments where the plurality of the modulators 301 are part of a single functioning unit/chip, at least one routing metal lead may be retained as a means of providing a common reference potential across the plurality. For such an embodiment, the bifurcation operation 170 (FIG. 1B) may entail separating one metal lead from a poling pad (e.g., 274) while retaining the remainder as a single segment that shorts together one electrode from each modulator to serve as a common reference potential (e.g., ground) plane.

FIG. 3B further illustrates the plurality of optical modulators 301 after the gang poling operation 150 and after bifurcation of the metal leads 281, 282. As shown, the metal leads 281, 282 are bifurcated into segments 281A, 281B, 281N and 282A, 282B, 282N, respectively, such that for n modulators, n metal lead segments having end surfaces 283 are electrically connected to only one electrode. For example, metal lead segment 281A is coupled only to electrode 231A and metal lead segment 282A is coupled only to electrode 232A.

In embodiments, after bifurcation of the routing metal leads, each of the separate lead segments remain coupled to drive signal routing. In the exemplary embodiment illustrated in FIGS. 3A and 3B, I/O pads 291A, 291B, 291N are coupled to the routing metal lead 281 and one I/O pad remains coupled to each individual lead segment (and therefore an individual electrode) after bifurcation of the lead 281. Similarly I/O pads 292A, 292B, and 292N are coupled to the metal routing lead 282 with one I/O pad remaining coupled to each individual lead segment (and therefore an individual electrode) after bifurcation of the lead 282. The I/O pads are illustrated in dashed line to emphasize that such drive signal routing may be implemented in the same metal level as the routing metal leads 281, 282, as it is in one embodiment, or in a separate metal level.

In embodiments, following EOP poling and metal lead bifurcation, the method 102 proceeds with completing the devices at operation 190. For certain embodiments, operation 190 entails a passivation film deposition (e.g., CVD silicon nitride, etc.). The substrate may then be diced/packaged into separate die/chips.

To further illustrate the broad applicability of the method 102 to a variety of EOP-based photonic devices, a ring oscillator (RO) modulator embodiment is illustrated in FIGS. 3C and 3D. As shown in FIG. 3C, the plurality of devices 303 includes RO modulators 304A, 304B, and 304N. Each RO modulator further includes a circular waveguide (e.g., 211A, 211B, and 211N) optically coupled to an I/O waveguide (e.g., 210A, 210B, and 210N). Routing metal leads 281, 282 again couple separate electrodes (e.g., 231A-N and 232A-N) of the n modulators together in parallel to the poling probe pads 273, 274. As shown in FIG. 3D, after poling the EOP materials (not depicted) disposed between the coplanar electrodes with in-plane fields, the metal leads 281, 282 are bifurcated substantially as was described for in the context of the MZ optical modulators 204A-204N (FIG. 3B).

FIG. 4A is cross-sectional view of a plurality of photonic devices during poling, in accordance with an embodiment. FIG. 4B is cross-sectional view of a plurality of photonic devices in operative states, in accordance with an embodiment. The FIGS. 4A and 4B generally illustrate the electrode coplanarity applicable to the exemplary embodiments illustrated in FIGS. 2A-2C and 3A-3D. Specifically, the electrodes 231A and 232A, composed of any conventional metal, polysilicon, etc. are disposed over the substrate 401 and on either side of the waveguide 211A. The EOP material 221A is disposed over the waveguide 211A, and spaces apart the coplanar electrodes 231A and 232A. In a second level of metal, the routing metal lead 282 extends between a first photonic device (e.g., optical modulator) and an adjacent, second optical device that is substantially identical.

Disposed over the EOP material 221A (and 221B) is a passivation layer 450 that is deposited after poling, but prior to bifurcation of the routing metal employed to gang pole a plurality of photonic devices. The passivation layer 450 is to protect the EOP material from exposure to the bifurcation process. As shown in FIG. 4B, the bifurcation process separates the metal lead 282 into two segments 282A and 282B, for example by etching through a region of the metal lead 282 with any conventional patterning process. After bifurcation, a second passivation layer 455 is deposited over end surfaces 282 of the first and second metal lead segments exposed by the bifurcating, and over the first passivation layer 450.

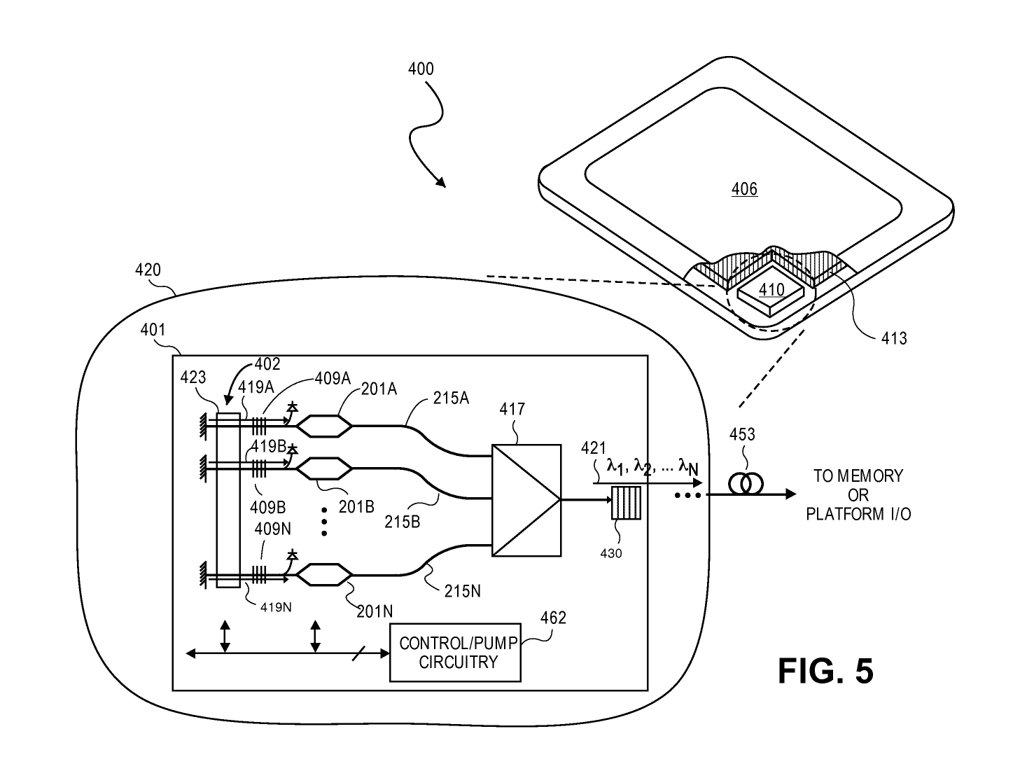

While the EOP-based photonic devices and fabrication techniques described herein may be utilized individually or in combination within many system-level applications, FIG. 5 is a schematic diagram of a mobile computing platform including an exemplary optical transmitter in accordance with embodiments of the present invention. The mobile computing platform 400 may be any portable device configured for each of electronic data display, electronic data processing, and wireless electronic data transmission. For example, mobile computing platform 400 may be any of a laptop, a netbook, a notebook, an ultrabook, a tablet, a smart phone, etc. and includes a display screen 406, which may be a touchscreen (e.g., capacitive, resistive, etc.) the optical transmitter 410, and a battery 413.

The optical transmitter 410 is further illustrated in the expanded functional block view 420 illustrating an array of electrically pumped lasers 402 controlled by circuitry 462 coupled to a passive semiconductor layer over, on, or in, substrate 401. The semiconductor substrate 401 further includes a plurality of optical waveguides 215A-215N. During operation, a plurality of optical beams 419A-419C are generated (e.g., with array of hybrid lasers including a bar of III-V semiconductor gain medium material 423 is bonded to create and reflectors 409A-409N) and conducted within the plurality of optical waveguides 215A-215N. The plurality of optical beams 419A-419N are modulated by the modulators 201A-201N (e.g., in-plane push-pull modulators as described elsewhere herein) and selected wavelengths are combined in with optical add-drop multiplexer 417 to output a single optical beam 421 through a grating coupler 430, which is then optically coupled into an optical wire 453. The optical wire 453 is further coupled to a downstream optical receiver external to the mobile computing platform 400 (i.e., coupled through the platform optical I/O terminal) or is further coupled to a downstream optical receiver internal to the mobile computing platform 400 (i.e., a memory module).

In one embodiment, the optical wire 453 is capable of transmitting data at the multiple wavelengths included in the optical beam 421 at speeds of at least 25 Gb/s and potentially more than 1 Tb/s. In one example, the plurality of optical waveguides 215A-215N are in a single silicon layer for an entire bus of optical data occupying a PIC chip of less than 4 mm on a side.

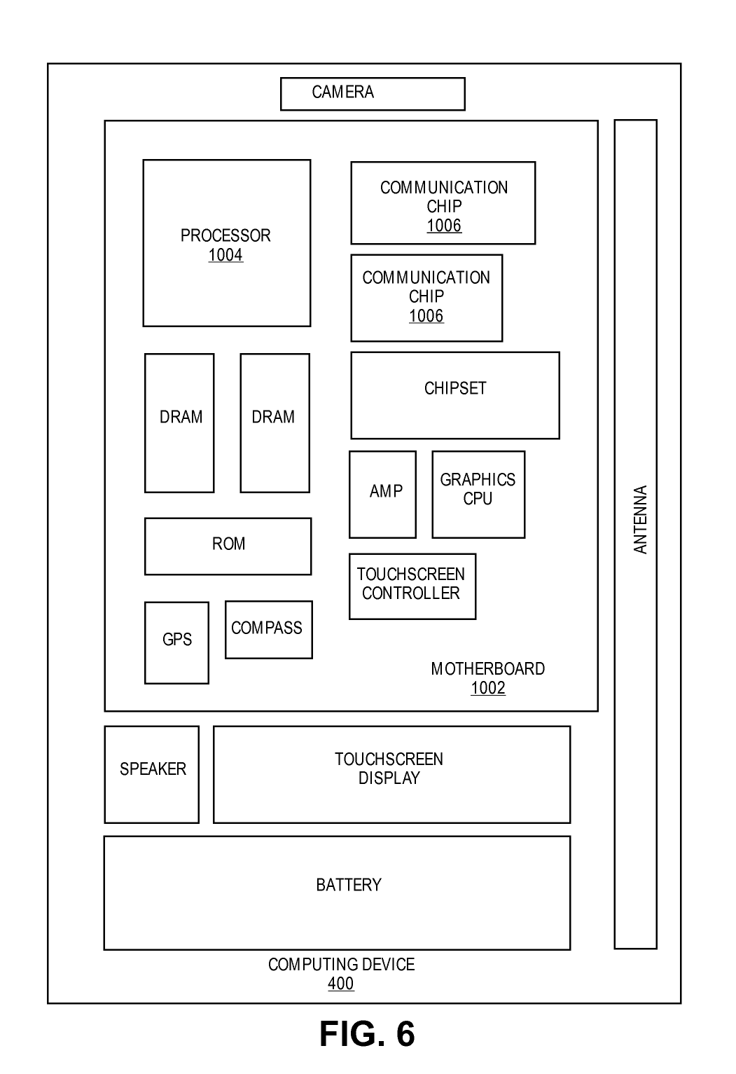

FIG. 6 is a functional block diagram of the mobile computing platform 400 in accordance with one embodiment of the invention. The mobile computing platform 400 includes a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004. Depending on its applications, mobile computing platform 400 may include other components that may or may not be physically and electrically coupled to the board 1002. These other components include, but are not limited to, volatile memory (e.g., DRAM), non-volatile memory (e.g., ROM), flash memory, a graphics processor, a digital signal processor, a crypto processor, a chipset, an antenna, touchscreen display, touchscreen controller, battery, audio codec, video codec, power amplifier, global positioning system (GPS) device, compass, accelerometer, gyroscope, speaker, camera, and mass storage device (such as hard disk drive, solid state drive (SSD), compact disk (CD), digital versatile disk (DVD), and so forth).

At least one of the communication chips 1006 enables wireless communications for the transfer of data to and from the mobile computing platform 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The mobile computing platform 400 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 includes an integrated circuit die packaged within the processor 1004. The term “processor” may refer to any device or portion of a device that processes electronic data from registers and/or memory to transform that electronic data into other electronic data that may be stored in registers and/or memory. Either of the communications chip 1006 may entail the optical transmitter 100, substantially as described elsewhere herein.

Embodiments of EOP-based photonic devices and their manufacture have been described. In an embodiment, a photonic device includes a first and second optical waveguide; a first EOP region optically coupled to the first optical waveguide; a second EOP region optically coupled to the second optical waveguide, a first electrode laterally spaced apart from a second electrode with the first EOP region disposed there between; and a third electrode laterally spaced apart from a fourth electrode with the second EOP region disposed there between, wherein the second EOP region has an in-plane pole direction opposite that of the first EOP region.

In further embodiments, the first and second optical waveguides are optically coupled to each other at opposite ends of the first and second EOP regions to form separate arms of an optical modulator. In further embodiments, the photonic device includes first routing metal electrically coupling a first pair of the electrodes; and second routing metal electrically coupling a second pair of the electrodes to increase a refractive index of the first EOP region and decrease the refractive index of the second EOP region when a signal is applied across the first and second routing metal. In further embodiments, the first, second, third, and fourth electrodes are coplanar, and the first routing metal comprises a first pair of vias coupled to the second and third electrodes, and the second routing metal comprises a second pair of vias coupled to the first and fourth electrodes. In further embodiments, first poling probe pads are coupled to the first routing metal; and second poling probe pads are coupled to the second routing metal. In further embodiments, each of the first pair of vias is coupled to one of a first pair of metal leads crossing at least one of the electrodes, and each of the first pair of metal leads is coupled to an individual one of the first poling probe pads; and each of the second pair of vias is coupled to one of a second pair of metal leads crossing at least one of the electrodes, and each of the second pair of metal leads is coupled to an individual one of the second poling pads. In further embodiments, at least one of the second pair of electrodes is disposed between ones of the first pair of electrodes to separate the first pair of electrodes with a fixed voltage reference plane.

In embodiments, a photonic integrated circuit (PIC), includes n optical modulators, wherein each optical modulator includes an optical waveguide passing between a pair of coplanar electrodes and optically coupled to an EOP region disposed between the pair of electrodes; at least two poling probe pads; and at least two bifurcated metal leads, wherein each of the bifurcated metal leads includes at least one segment that is electrically connected by a via to one of the electrodes, and is electrically isolated from the poling probe pads. In further embodiments, each of the bifurcated metal leads includes at least n segments and each of the n segments is electrically connected to only one of the electrodes. In further embodiments, each of the n segments are coupled to an I/O pad. In further embodiments, each of the n optical modulators is a Mach-Zehnder (MZ) modulator or a ring oscillator. In further embodiments, each of the n optical modulators is a push-pull MZ modulator further comprising: a first and second optical waveguide; a first EOP region optically coupled to the first optical waveguide; a second EOP region optically coupled to the second optical waveguide, a first electrode laterally spaced apart from a second electrode with the first EOP region disposed there between; and a third electrode laterally spaced apart from a fourth electrode with the second EOP region disposed there between; and wherein the second EOP region has an in-plane polarity opposite that of the first EOP region, and wherein the at least twp poling probe pads comprises at least four poling probe pads; and the at least two bifurcated metal leads comprises at least four bifurcated metal leads. In further embodiment, the poling probe pads have probe marks resulting from physical contact by a probe.

In an embodiment, a photonic device includes a first and second optical waveguide; a first EOP region optically coupled to the first optical waveguide; a second EOP region optically coupled to the second optical waveguide, a first electrode laterally spaced apart from a second electrode with the first EOP region disposed there between; a third electrode laterally spaced apart from a fourth electrode with the second EOP region disposed there between, wherein the first, second, third, and fourth electrodes are coplanar; a first bifurcated metal lead comprising first metal lead segments, wherein a first of the first segments is electrically coupled to the first electrode, a second of the first segments is electrically coupled to the third electrode, and a third of the first segments is electrically coupled to a first poling probe pad. In further embodiments, the photonic device includes a second bifurcated metal lead comprising second coplanar metal lead segments disposed on a same plane as the first segments, a first of the second segments is coupled to the second electrode, a second of the second segments is coupled to the fourth electrode, and a third of the second segments is coupled to a second poling probe pad. In further embodiments, the first poling probe pad is electrically isolated from the electrodes and the first poling probe pad has probe marks resulting from physical contact by a probe. In further embodiments, a first plurality vias, each coupling one of the first metal lead segments to one of the first and third electrodes; and a second plurality of vias, each coupled one of the second metal segments to one of the second and fourth electrodes.

In embodiments, a method of fabricating a photonic device, the method includes receiving the photonic device disposed on a substrate, wherein the photonic device includes a first electrode laterally spaced apart from a second electrode with a first EOP region disposed there between; and a third electrode laterally spaced apart from a fourth electrode with a second EOP region disposed there between; and applying a voltage to the second and third electrodes relative to the first and fourth electrodes to generate an in-plane field across the first EOP region that opposes an in-plane field across the second EOP region. In embodiments, the method further includes electrically coupling the second and fourth electrodes with first metal routing and electrically coupling the first and third electrodes with second metal routing to increase an index of one of the first and second EOP regions and decrease an index of another of the first and second EOP regions when a signal is applied across the first and second metal routing. In embodiments, the first electrode is coupled to a first poling probe pad, the second electrode is coupled to a second poling probe pad, the third electrode is coupled to a third poling probe pad, and the fourth electrode is coupled to a fourth poling probe pad, and applying the voltage further comprises: landing probes of a probe card onto the poling probe pads and applying a voltage to the second and third poling probe pads relative to a reference voltage applied to the first and fourth poling probe pads. In further embodiments, the method includes forming a first and second optical waveguide; depositing the first EOP material in contact with the first waveguide and the second EOP material in contact with the second waveguide; connecting the second and third poling probe pads to the second and third electrodes, respectively, with a first routing metal; and connecting the first and fourth poling probe pads to the first and fourth electrodes, respectively, with a second routing metal. In further embodiments, the connecting with the first routing metal further comprises forming a first pair of metal leads, each coupled to one of the second and third poling pads by at least one via; and wherein the connecting with the second routing metal further comprises forming a second pair of metal leads, each coupled to one of the first and fourth poling pads by at least one via.

In embodiments, a method of fabricating a plurality of photonic devices, the method includes receiving the plurality of photonic devices disposed over a substrate, each device comprising first and second electrodes spaced apart with an EOP region disposed there between, wherein the first electrodes are coupled to a first poling probe pad by a first metal lead, and wherein the second electrodes are coupled to a second poling probe pad by a second metal lead; applying a voltage between a first and second poling probe pads to induce an electric field across EOP regions of the plurality of EOP devices concurrently; curing the plurality of poled EOP regions; and bifurcating the first and second metal leads to separate the first and second electrodes from the first and second poling probe pads. In a further embodiment, the method includes forming the first and second electrodes in a first metal level; forming the first and second metal leads in a second metal level joined to the first metal level by vias; and wherein the electric fields induced are in the plane of the substrate. In a further embodiment, bifurcating the first and second metal leads further comprises separating the first electrodes from each other and separating the second electrodes from each other. In a further embodiment, bifurcating the first and second metal leads comprises at least one of etching or polishing through portions of the first and second metal leads extending between ones of the photonic devices. In a further embodiment, the method further includes depositing a first passivation layer over the EOP regions; and depositing a second passivation layer over end surfaces of the first and second metal leads exposed by the bifurcating, and over the first passivation layer.

It is to be understood that the above description is illustrative, and not restrictive. For example, while flow diagrams in the figures show a particular order of operations performed by certain embodiments of the invention, it should be understood that such order may not be required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A photonic device comprising:
a first and second optical waveguide;
a first EOP region optically coupled to the first optical waveguide;
a second EOP region optically coupled to the second optical waveguide,
a first electrode laterally spaced apart from a second electrode with the first EOP region disposed there between; and
a third electrode laterally spaced apart from a fourth electrode with the second EOP region disposed there between, wherein the second EOP region has an in-plane pole direction opposite that of the first EOP region.

2. The photonic device of claim 1, wherein the first and second optical waveguides are optically coupled to each other at opposite ends of the first and second EOP regions to form separate arms of an optical modulator.

3. The photonic device of claim 1, further comprising:
first routing metal electrically coupling a first pair of the electrodes; and
second routing metal electrically coupling a second pair of the electrodes to increase a refractive index of the first EOP region and decrease the refractive index of the second EOP region when a signal is applied across the first and second routing metal.

4. The photonic device of claim 3, wherein the first, second, third, and fourth electrodes are coplanar, and wherein the first routing metal comprises a first pair of vias coupled to the second and third electrodes, wherein the second routing metal comprises a second pair of vias coupled to the first and fourth electrodes.

5. The photonic device of claim 4, further comprising:
first poling probe pads coupled to the first routing metal; and
second poling probe pads coupled to the second routing metal.

6. The photonic device of claim 5, wherein each of the first pair of vias is coupled to one of a first pair of metal leads crossing at least one of the electrodes, and each of the first pair of metal leads is coupled to an individual one of the first poling probe pads; and
wherein each of the second pair of vias is coupled to one of a second pair of metal leads crossing at least one of the electrodes, and wherein each of the second pair of metal leads is coupled to an individual one of the second poling pads.

7. The photonic device of claim 6, wherein at least one of the second pair of electrodes is disposed between ones of the first pair of electrodes to separate the first pair of electrodes with a fixed voltage reference plane.

8. A photonic integrated circuit (PIC), comprising:
n optical modulators, wherein each optical modulator includes an optical waveguide passing between a pair of coplanar electrodes and optically coupled to an EOP region disposed between the pair of electrodes;
at least two poling probe pads; and
at least two bifurcated metal leads, wherein each of the bifurcated metal leads includes at least one segment that is electrically connected by a via to one of the electrodes, and is electrically isolated from the poling probe pads.

9. The PIC of claim 8, wherein each of the bifurcated metal leads includes at least n segments and each of the n segments is electrically connected to only one of the electrodes.

10. The PIC of claim 9, wherein each of the n segments are coupled to an I/O pad.

11. The PIC of claim 9, each of the n optical modulators is a Mach-Zehnder (MZ) modulator or a ring oscillator.

12. The PIC of claim 11, wherein each of the n optical modulators is a push-pull MZ modulator further comprising:
a first and second optical waveguide;
a first EOP region optically coupled to the first optical waveguide;
a second EOP region optically coupled to the second optical waveguide,
a first electrode laterally spaced apart from a second electrode with the first EOP region disposed there between; and
a third electrode laterally spaced apart from a fourth electrode with the second EOP region disposed there between; and
wherein the second EOP region has an in-plane polarity opposite that of the first EOP region, and wherein the at least twp poling probe pads comprises at least four poling probe pads; and the at least two bifurcated metal leads comprises at least four bifurcated metal leads.

13. The PIC of claim 8, wherein the poling probe pads have probe marks resulting from physical contact by a probe.

14. A photonic device comprising:
a first and second optical waveguide;
a first EOP region optically coupled to the first optical waveguide;
a second EOP region optically coupled to the second optical waveguide,
a first electrode laterally spaced apart from a second electrode with the first EOP region disposed there between;
a third electrode laterally spaced apart from a fourth electrode with the second EOP region disposed there between, wherein the first, second, third, and fourth electrodes are coplanar;
a first bifurcated metal lead comprising first metal lead segments, wherein a first of the first segments is electrically coupled to the first electrode, a second of the first segments is electrically coupled to the third electrode, and a third of the first segments is electrically coupled to a first poling probe pad.

15. The device of claim 14, further comprising a second bifurcated metal lead comprising second coplanar metal lead segments disposed on a same plane as the first segments, wherein a first of the second segments is coupled to the second electrode, a second of the second segments is coupled to the fourth electrode, and a third of the second segments is coupled to a second poling probe pad.

16. The device of claim 14, wherein the first poling probe pad is electrically isolated from the electrodes and wherein the first poling probe pad has probe marks resulting from physical contact by a probe.

17. The device of claim 14, further comprising:
a first plurality vias, each coupling one of the first metal lead segments to one of the first and third electrodes; and
a second plurality of vias, each coupled one of the second metal segments to one of the second and fourth electrodes.

18. A method of fabricating a photonic device, the method comprising:
receiving the photonic device disposed on a substrate, wherein the photonic device comprises:
a first electrode laterally spaced apart from a second electrode with a first EOP region disposed there between; and
a third electrode laterally spaced apart from a fourth electrode with a second EOP region disposed there between; and
applying a voltage to the second and third electrodes relative to the first and fourth electrodes to generate an in-plane field across the first EOP region that opposes an in-plane field across the second EOP region.

19. The method of claim 18, further comprising, electrically coupling the second and fourth electrodes with first metal routing and electrically coupling the first and third electrodes with second metal routing to increase an index of one of the first and second EOP regions and decrease an index of another of the first and second EOP regions when a signal is applied across the first and second metal routing.

20. The method of claim 18, wherein the first electrode is coupled to a first poling probe pad, the second electrode is coupled to a second poling probe pad, the third electrode is coupled to a third poling probe pad, and the fourth electrode is coupled to a fourth poling probe pad, and wherein applying the voltage further comprises:
landing probes of a probe card onto the poling probe pads and applying a voltage to the second and third poling probe pads relative to a reference voltage applied to the first and fourth poling probe pads.

21. The method of claim 18, further comprising:
forming a first and second optical waveguide;
depositing the first EOP material in contact with the first waveguide and the second EOP material in contact with the second waveguide;
connecting the second and third poling probe pads to the second and third electrodes, respectively, with a first routing metal; and
connecting the first and fourth poling probe pads to the first and fourth electrodes, respectively, with a second routing metal.

22. The method of claim 21, wherein the connecting with the first routing metal further comprises forming a first pair of metal leads, each coupled to one of the second and third poling pads by at least one via; and wherein the connecting with the second routing metal further comprises forming a second pair of metal leads, each coupled to one of the first and fourth poling pads by at least one via.

23. A method of fabricating a plurality of photonic devices, the method comprising:
receiving the plurality of photonic devices disposed over a substrate, each device comprising first and second electrodes spaced apart with an EOP region disposed there between, wherein the first electrodes are coupled to a first poling probe pad by a first metal lead, and wherein the second electrodes are coupled to a second poling probe pad by a second metal lead;
applying a voltage between a first and second poling probe pads to induce an electric field across EOP regions of the plurality of EOP devices concurrently;
curing the plurality of poled EOP regions; and
bifurcating the first and second metal leads to separate the first and second electrodes from the first and second poling probe pads.

24. The method of claim 23, further comprising:
forming the first and second electrodes in a first metal level;
forming the first and second metal leads in a second metal level joined to the first metal level by vias; and
wherein the electric fields induced are in the plane of the substrate.

25. The method of claim 23, wherein bifurcating the first and second metal leads further comprises separating the first electrodes from each other and separating the second electrodes from each other.

26. The method of claim of claim 23, wherein bifurcating the first and second metal leads comprises at least one of etching or polishing through portions of the first and second metal leads extending between ones of the photonic devices.

27. The method of claim 23, further comprising:
depositing a first passivation layer over the EOP regions; and
depositing a second passivation layer over end surfaces of the first and second metal leads exposed by the bifurcating, and over the first passivation layer.
